(19) United States
(12) Patent Application Publication
(10) Pub. No.: US 2010/0126764 A1
(43) Pub. Date: May 27, 2010

(54) DIE GROUND LEAD

(75) Inventor: William Leon Rugg, Longmont, CO (US)

Correspondence Address: HENSLEY KIM & HOLZER, LLC, 1660 LINCOLN STREET, SUITE 3000, DENVER, CO, 80264, US

(73) Assignee: Seagate Technology, LLC, Scotts Valley, CA (US)

(21) Appl. No.: 12/277,165

(22) Filed: Nov. 24, 2008

(51) Int. Cl. H01R 12/02; H05K 3/32

(52) U.S. Cl. 174/262; 29/842

(57) ABSTRACT

In order to improve signal to noise ratio and reduce electromagnetic interference, it is presently contemplated to connect ground potential on an electronic package mounted to a printed circuit board directly to a commonly grounded surface of a device via an improved die ground lead with a first end connected to an electrical circuit within the electronic package, and a second end extending away from the electronic package and compressively contacting, rather than forming a bonded or soldered connection to, the commonly grounded surface. By way of example and not limitation, the improved die ground lead may be any one of a tie bar, a metal lead, a pogo pin, and a spring. The use of this configuration for the ground connection between the electrical circuit and the commonly grounded surface results in significantly less physical distance than conventional ground paths for electrical circuits within electronic packages.

### SUMMARY

Hard disk drive (HDD) design continues to progress toward faster, smaller, lighter, and generally more efficient devices. Such designs necessarily lead to wires within such devices carrying or affecting signals with increasingly smaller amplitudes. These small amplitude signals are especially vulnerable to electronic interference from other nearby wires and/or devices.

In order to improve signal to noise ratio (SNR) and reduce electromagnetic interference (EMI) in an electronic package ground connection, a novel approach connects ground potential of an electrical circuit within an electronic package directly to a commonly grounded surface of an electrical system (e.g., a commonly grounded housing of an HDD). In one implementation, an improved die ground lead includes a first end internally connected to an electrical ground potential of the electrical circuit within the electronic package and a second end creating a compressive electrical connection with the commonly grounded surface.

The use of this configuration for the improved die ground connection between the electrical circuit and the commonly grounded surface results in significantly less physical distance than conventional ground paths for electronic packages. Conventional ground paths typically extend through a printed circuit board (PCB), along the PCB surface and then down through mounting screws to the commonly grounded housing. Since conventional ground paths typically utilize the PCB as an intermediary between the electronic package and the commonly grounded housing, the length of the ground connection is increased and therefore the resulting noise and possibility of EMI is increased.

This Summary is provided to introduce a selection of concepts in a simplified form that are further described below in the Detailed Description. This Summary is not intended to identify key features or essential features of the claimed subject matter, nor is it intended to be used to limit the scope of the claimed subject matter. Other features, details, utilities, and advantages of the claimed subject matter will be apparent from the following more particular written Detailed Description of various implementations and implementations as farther illustrated in the accompanying drawings and defined in the appended claims.

### BRIEF DESCRIPTION OF THE DRAWINGS

The described technology is best understood from the following Detailed Description describing various implementations read in connection with the accompanying drawings.

FIG. 1 illustrates a perspective view of an example HDD assembly with an electronic package mounted to a PCB and the PCB mounted to the commonly grounded housing of the HDD.

FIG. 2 illustrates a first sectional view of an example HDD assembly of FIG. 1 utilizing a tie bar improved die ground lead.

FIG. 3 illustrates a second sectional view of an example HDD assembly of FIG. 1 utilizing a pogo pin improved die ground lead.

FIG. 4 illustrates a plan view of the interior of an example electronic package with a tie bar extending out of one corner of the electronic package.

FIG. 5 illustrates a plan view of the exterior of an example electronic package with a tie bar extending outwardly from one corner and folded over the top of the electronic package.

FIG. 6 illustrates a perspective view of an example electronic package mounted on a PCB with a tie bar improved die ground lead contacting a commonly grounded surface.

FIG. 7 illustrates a perspective view of an example electronic package mounted on a PCB with a pogo pin improved die ground lead contacting a commonly grounded surface.

FIG. 8 is a flow chart illustrating an example process for assembling an electrical system with an improved die ground lead.

FIG. 9 is a flow chart illustrating another example process for assembling an electrical system with an improved die ground lead.

### DETAILED DESCRIPTION

The market for HDDs continues to demand increased performance and storage capability from increasingly smaller and lighter devices while requiring less power to operate. This progression toward faster, smaller, lighter, and generally more efficient designs leads to wires within such devices carrying or affecting signals with increasingly smaller amplitudes. These small amplitude signals are especially vulnerable to electromagnetic interference from other nearby wires and/or devices.

By minimizing the length of ground connections associated with sensitive circuitry that relies on small amplitude signals, noise and EMI effects on such signals can be reduced. As such, an improved die ground lead described herein provides a reduced ground connection length and therefore results in a reduction in noise and EMI effects experienced by the sensitive circuitry. Specifically, the improved die ground lead reduces the distance the ground connection must travel from an electronic package to a commonly grounded surface of an electrical system. The commonly grounded surface may be any conductive surface that serves as a common ground for the electrical system, by example and not limitation, a commonly grounded housing.

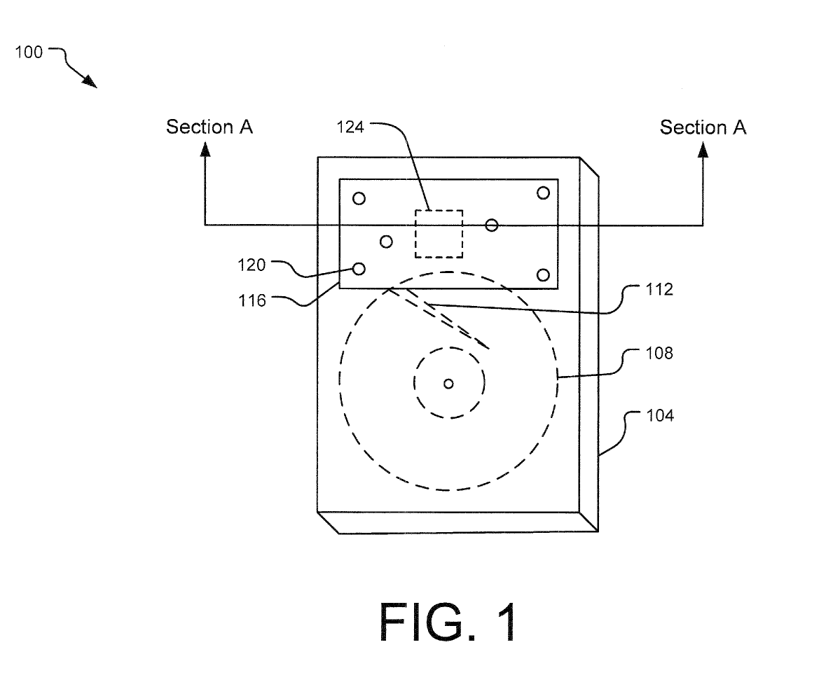

Referring now to FIG. 1, an example perspective layout of a HDD 100 is shown generally comprising a commonly grounded housing 104 within which at least one platter 108 and at least one actuator 112 are mounted. A PCB 116 is mounted to an outer surface of the commonly grounded housing 104 using screws inserted through screw holes 120 in the PCB 116 and the housing 104. At least one electronic package 124 through which the HDD 100 is controlled is mounted on the surface of the PCB 116 between the PCB 116 and the commonly grounded housing 104.

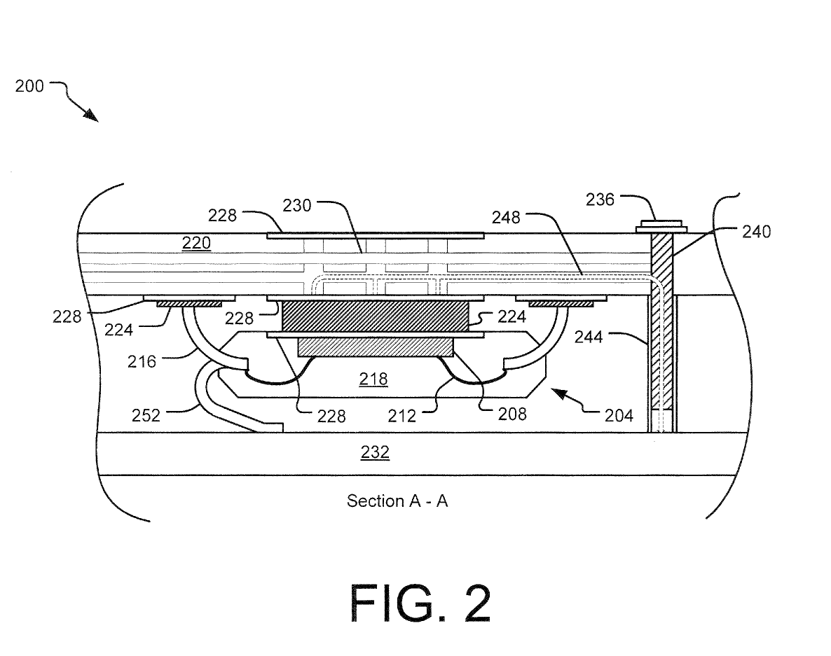

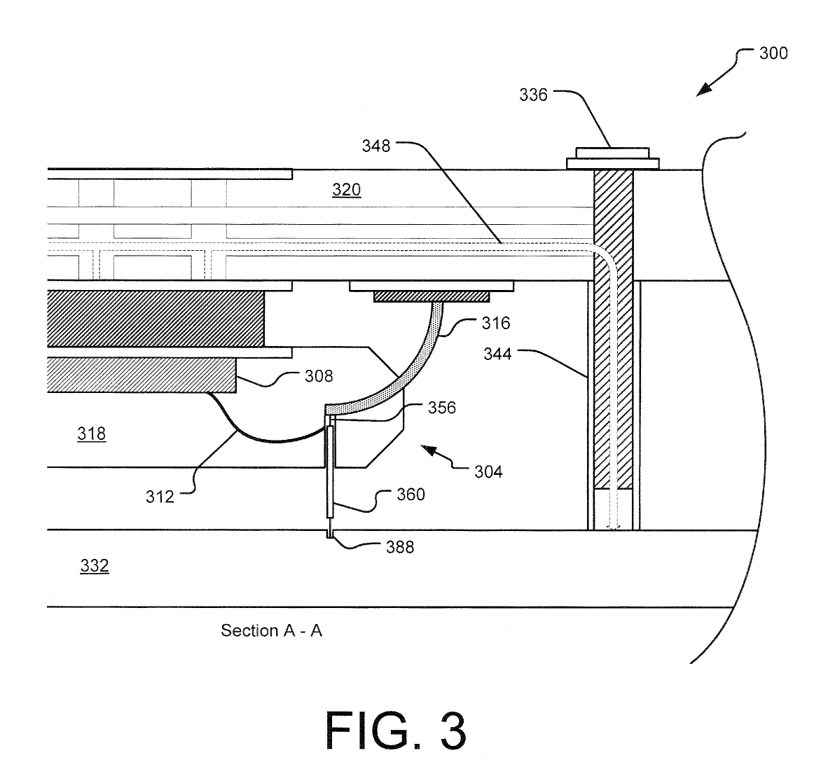

According to the presently disclosed technology, an improved die ground connection from the electrical circuit within the electronic package 124 to a surface of the commonly grounded housing 104 is established via an improved die ground lead extending from ground potential within the electrical circuit to the surface of the commonly grounded housing 104 to establish a compressive contact with the commonly grounded housing 104. The improved die ground lead may be any compressive electrical connection, including but not limited to, a compression connector, a tie bar, a pogo pin, a spring, and any other compressive electrical connection, such that the electrical connection maintains integrity with a surface of the commonly grounded housing 104 during operation without bonding or soldering or passing through or along the PCB 116. Section A-A of the HDD 100 in the area of the PCB 116 is shown in detail in FIGS. 2 and 3.

The HDD 100 is used as an example only; the disclosed technology may be utilized in a variety of electrical systems utilizing a commonly grounded surface, a PCB 116, and at least one electronic package 124, e.g., cellular telephones, PDAs, and various computer components. Further, the electronic package 124 may be any type of electrical system where an improved die ground lead is desired, e.g., microprocessors, microcontrollers, application-specific integrated circuits, digital field processors, and field-programmable field arrays.

Additionally, the improved die ground lead may be adapted to a variety of electronic packaging styles, for example, ball grid array (BGA) packaging and lead frame packaging. In the BGA implementation, the interface between the PCB 116 and the electronic package 124 comprises a grid of solder balls on a surface of the electronic package 124 facing the PCB 116. These solder balls conduct electrical signals from the electronic package 124 to the PCB 116 and vice versa. Example BGA implementations contemplated herein include but are not limited to, ceramic BGA, plastic BGA, fine BGA, ultra fine BGA, and micro BGA.

In the lead frame implementation, a die attach pad of the electronic package 124 is exposed and directly attached to the PCB 116. Further, leads may extend from the die and attach to the PCB 116. Depending on the style of lead frame packaging, the leads may extend out of the electronic package 124 before attaching to the PCB 116 or the leads may attach to the PCB 116 where the surface of the electronic package 124 adjoins the PCB 116 (e.g., is in direct physical contact with the PCB 116 or in indirect physical contact with the PCB 116, such as through an adhesive and/or solder layer). Example lead frame implementations contemplated herein include but are not limited to, micro lead frame package (MLP), MLP quad, MLP micro, MLP dual, thin quad flat pack (TQFP), quad flat no leads (QFN), fusionquad, very very fine land grid array (WPLGA), thin array plastic package (TAPP), and thin substrate chip scale package (tsCSP).

Referring now to FIG. 2, an example electrical system 200 utilizing an improved die ground lead is shown. An electronic package 204 is shown with a die 208 mounted therein. At least one wire 212 connects the die 208 to at least one signal lead 216. The connections between the die 208, the wire 212, and the signal lead 216 are sealed in an over mold 218 formed from Bakelite or any other electrically non-conductive moldable or non-moldable material.

The signal lead 216 connects the die 208 and wire(s) 212 (collectively, the electrical circuit) within the electronic package 204 to a PCB 220 via at least one soldered connection 224 to at least one contact pad 228 on the PCB 220. The electronic package 204 may be further adjoined to the PCB 220 via a soldered connection 224 between two contact pads 228, one on a surface of the PCB 220 and one on an adjacent surface of the electronic package 204. This soldered connection 224 may further carry though the thickness of the PCB 220 via circuit pathways 230 to another contact pad 228 on the opposite side of the PCB 220. Electrical signals transmitted to and from the electrical circuit and the PCB 220 via one or more contact pads 228 are carried along a length and/or thickness of the PCB 220 via the circuit pathways 230.

In one implementation, the PCB 220 is physically mounted to a commonly grounded surface 232 via at least one conductive screw 236 extending through at least one screw hole 240 in the PCB 220 and into at least one conductive screw sleeve 244 mounted on the commonly grounded surface 232. A traditional (ground connection between the electrical circuit and the commonly grounded surface 232 is illustrated by the arrow 248. It should be understood, however, that the described technology may replace the traditional ground connection of arrow 248 in some implementations. In a typical electrical system 200 utilizing an electronic package 204 mounted on a PCB 220, the ground connection is transmitted from the die 208 through a soldered connection 224 to a contact pad 228 on the PCB 220. The ground connection then travels along a length of the PCB 220 via circuit pathways 230 to a screw hole 240. Then a conductive screw 236 is inserted through the hole and carries the ground signal to the commonly grounded surface 232 through the interface of the conductive screw 236 with the conductive screw sleeve 244.

In the implementation of FIG. 2 consistent with presently disclosed technology, the improved die ground configuration connects ground potential of the electrical circuit within the electronic package 204 with the commonly grounded surface 232 directly, without relying on the PCB 220 as an intermediary. In one implementation, an electrical connection from the die 208 extends through the over mold 218 and out of the electronic package 204 away from the PCB 220, compressively contacting the commonly grounded surface 232. The improved die ground lead may be installed in lieu of the traditional ground connection or in addition to the traditional ground connection.

In the implementation shown in FIG. 2, an improved die ground lead 252 is connected to the die 208 with a wire 212. The improved die ground lead 252 extends out of the side of the electronic package 204 and bends away from the PCB 220 and toward the commonly grounded surface 232 which is mounted in close proximity to but not contacting the electronic package 204. As the PCB 220 is installed on the commonly grounded surface 232 via one or more conductive screws 236 and conductive screw sleeves 244, the improved die ground lead 252 compressively contacts the commonly grounded surface 232 thereby creating an improved die ground connection from the electrical circuit to the commonly grounded surface 232 when compared with the traditional ground connection illustrated by the arrow 248. The traditional ground connection illustrated by the arrow 248 includes bonded connections, such as soldering and welding, such that the ground connection travels through and/or along the PCB 220 and through mechanical structures, such as screws, press-fitting leads, and riveting to the commonly grounded surface 232. Example structures for the improved die ground lead 252 include, but are not limited to, one or more compression connectors, tie bars, springs, and metal leads configured to electrically connect ground potential on the electrical circuit to the commonly grounded surface 232 by extending from the electronic package 204 and forming a compressive electrical connection to the commonly grounded surface 232, rather than forming a bonded or soldered connection with structures of the PCB 220, which is connected to the commonly grounded surface 232. Further, the improved die ground lead may comprise multiple improved die ground leads 252 extending from the commonly grounded surface 232 and compressively contacting the commonly grounded surface 232.

FIG. 3 illustrates another example implementation of an electrical system 300 utilizing an improved die ground lead. In this implementation, the over mold 318 in the electronic package 304 has an aperture 356 through the surface of the electronic package 304 facing the commonly grounded surface 332. This aperture 356 extends through the over mold 318 and terminates at a wire 312 connected to ground potential on the die 308. In other implementations, the aperture 356 may terminate at ground potential directly on the die 308 or at a signal lead 316 connected to ground potential on the die 308 via a wire 312.

Within and extending out and away from the aperture 356 and toward the commonly grounded surface 332 is a pogo pin 360. In other implementations, any other compressive lead may be used in place of the pogo pin 360, e.g., a spring. As the PCB 320 is installed on the commonly grounded surface 332 via one or more conductive screws 336 and conductive screw sleeves 344, the pogo pin 360 compressively contacts the commonly grounded surface 332 thereby creating an improved die ground connection from the electrical circuit within the electronic package 304 to the commonly grounded surface 332 when compared with a traditional ground connection illustrated by the arrow 348.

The pogo pin 360 may be located anywhere on the face of the electronic package 304 where it can make electrical contact with ground potential of the electrical circuit. Further, there may be multiple pogo pins 360 creating multiple improved die ground connections between the electrical circuit and the commonly grounded surface 332. In the implementation of FIG. 3, the commonly grounded surface 332 has an indention 388 in the commonly grounded surface that acts as a seat for one end of the pogo pin 360. In other implementations, there is no seat in the commonly grounded surface 332 for receiving one end of the pogo pin 360.

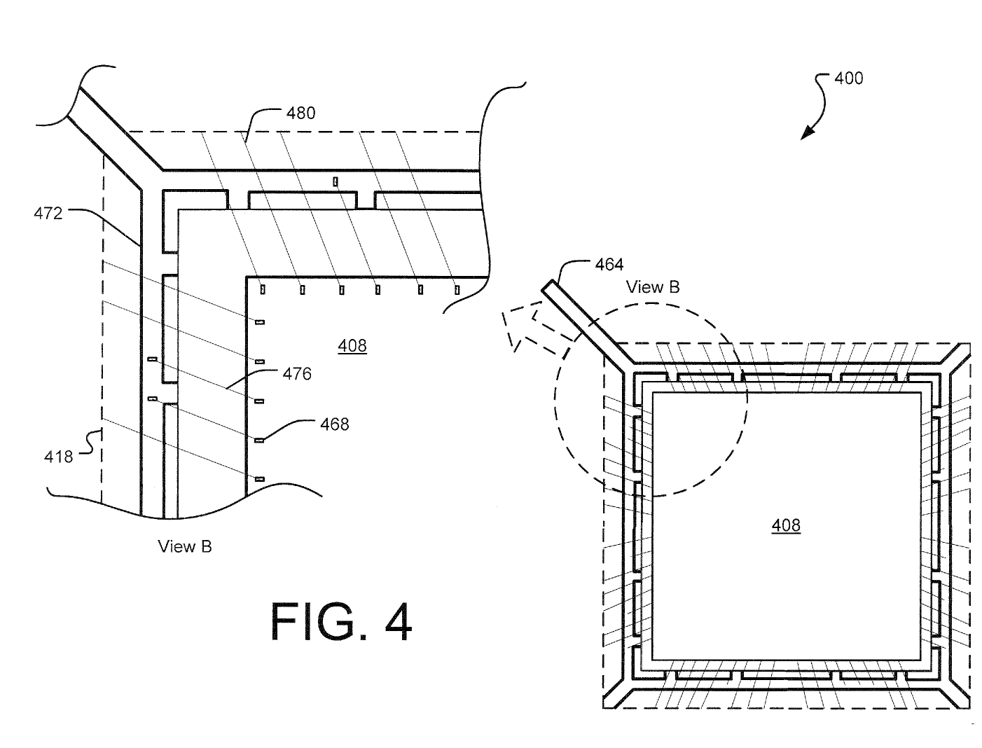

Referring now to FIG. 4, a plan view of the interior of an example electronic package 400 with a tie bar 464 extending out of one corner of the electronic package 400 is shown. The interior of this example electronic package 400, shown in detail in View B, comprises a die 408 with signal wires 480 and ground wires 476 extending from die pads 468 mounted on the die 408. The signal wires 480 extend to the periphery of the electronic package 400. The ground wires extend to die pads 468 mounted on a lead frame 472. The lead frame 472 serves as a common ground potential for the electrical circuit within the electronic package 400. A non-conductive material, known as over mold 418, may be used to encase the connections between the die 408, die pad 468, signal wires 480, ground wires 476, and lead frame 472 and protect them from potential damage from dirt, corrosion, or physical contact with another object.

Systems such as the electronic package 400 shown in FIG. 4 are often manufactured in stripes containing multiple electronic packages. The stripes are then cut to yield each individual electronic package 400. Normally the excess conductive material extending from the lead frame 472 out of the corners of the electronic package 400 is trimmed off when the stripes are cut. However, in the implementation shown in FIG. 4, a portion of the excess conductive material, known as a tie bar 464 is kept and may be used to provide the improved die ground connection as contemplated by the presently disclosed technology. Use of the tie bar 464 as an improved die ground lead is merely an example; other structures of making electrical contact with the lead frame 472 and/or ground wires 476 are contemplated to extend an improved die ground lead out of the electronic package 400.

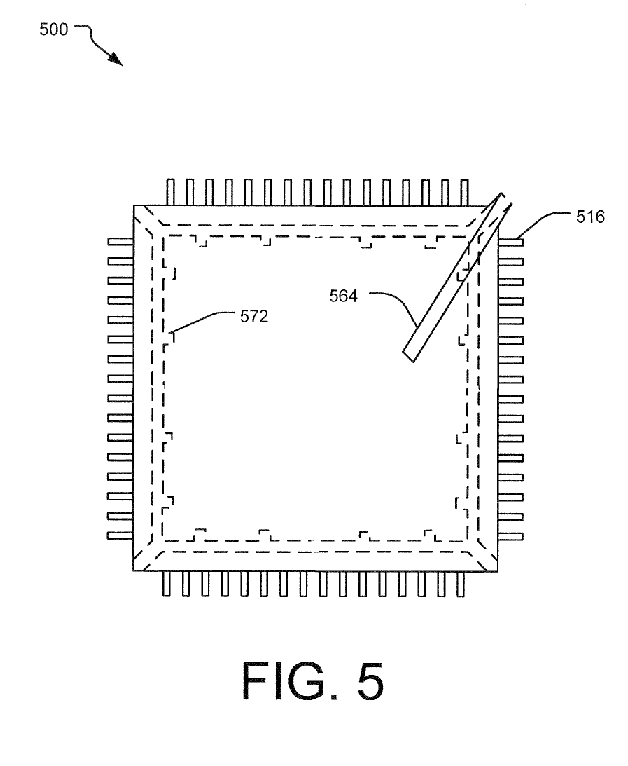

Referring now to FIG. 5, a plan view of the exterior of an example electronic package 500 with a tie bar 564 extending out of one corner of the electronic package 500 is shown. From the exterior, all that is visible are signal leads 516 protruding from each side of the electronic package 500, the tie bar 564 protruding from one corner of the electronic package 500, and over mold covering the internal components of the electronic package 500.

The lead frame 572 is shown in broken lines to illustrate the connection between the tie bar 564 and the lead frame 572, even though the lead frame 572 cannot actually be seen from this exterior view. The tie bar 564 extends out of a corner of the electronic package 500 and may be bent upwardly and over a first face of the electronic package 500, thereby creating an improved die ground lead that may compressively contact anything that is placed adjacent the first face of the electronic package 500.

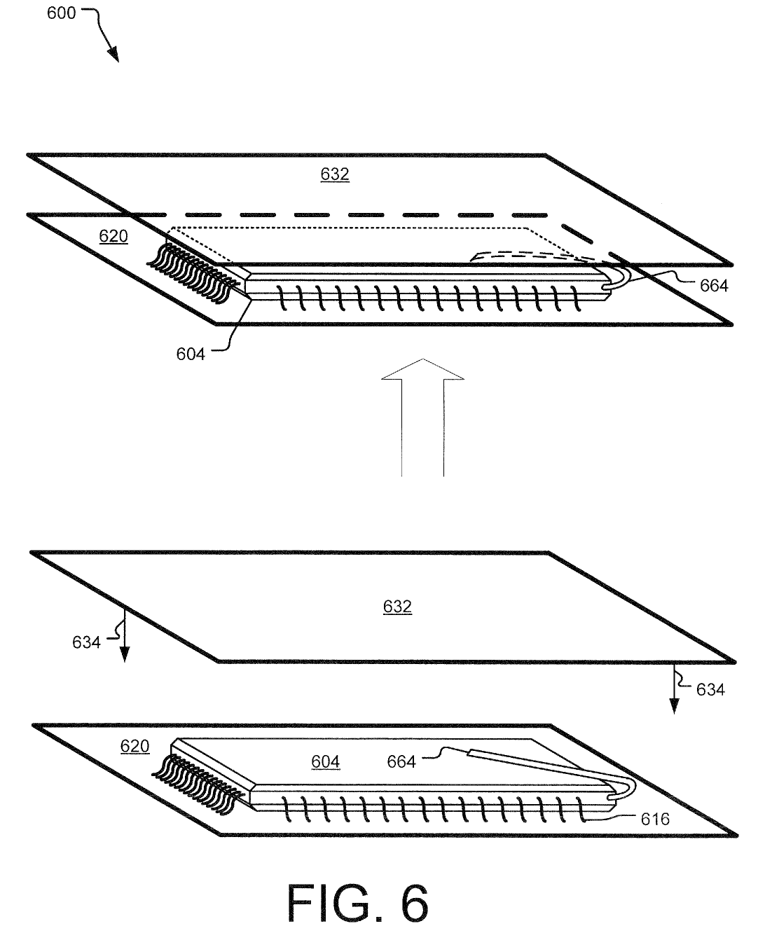

Referring now to FIG. 6, the electronic package 500 of FIG. 5 is shown mounted on a PCB 620 with a tie bar 664 improved die ground lead contacting a commonly grounded surface 632. More specifically, the electronic package assembly 600 is shown in “before installation” and “after installation” illustrations.

In the bottom, before installation illustration, an electronic package 604 similar to the one depicted in FIG. 5 is shown mounted on a plane representing a PCB 620. Signal leads 616 protrude from the sides of the electronic package 604 and attach to the PCB 620. The tie bar 664 emerges from a corner of the electronic package 604 and extends away from the PCB 620. The tie bar 664 is further bent so that it passes over the first face of the electronic package 604 while continuing to extend away from the PCB 620. A plane representing the commonly grounded surface 632 is shown above the electronic package 604 and arrows 634 indicate that the commonly grounded surface 632 will be moved in the direction of the electronic package 604.

In the top, after installation illustration, the PCB 620 with an electronics package 604 mounted thereto is shown installed on the plane representing the commonly grounded surface 632. After installation, a first face of the electronics package 604 is in close proximity, but not in contact with the commonly grounded surface 632. However, the tie bar 664 is in compressive contact with the commonly grounded surface 632, thereby connecting ground potential on the electrical circuit within the electronic package 604 to the commonly grounded surface 632 via the tie bar 664 without utilizing the PCB 620 as an intermediary.

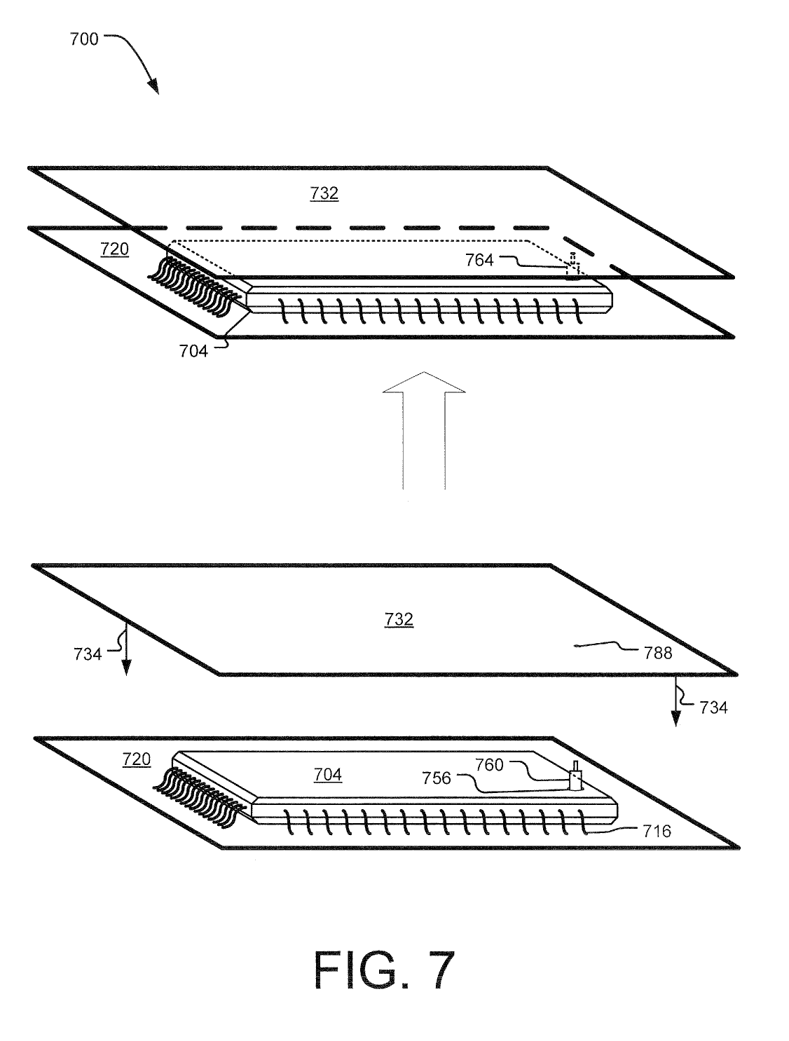

Referring now to FIG. 7, an electronics package 704 is shown mounted on a PCB 720 with a pogo pin 760 improved die ground lead contacting a commonly grounded surface 732. Similar to FIG. 6, the electronic package assembly 700 is shown in “before installation” and “after installation” illustrations.

In the bottom, before installation illustration, the electronic package 704 is shown mounted on a plane representing a PCB 720 in the same way described in FIG. 6. However, the electronic package 704 does not utilize a tie bar to extend an improved die ground connection out of the electronic package 704 and away from the PCB 720. Instead, the electronic package 704 illustrated in FIG. 7 utilizes a pogo pin 760 mounted within an aperture 756 in the over mold of the electronic package 704. The aperture 756 extends into the electronic package 704 to ground potential of an electrical circuit within the electronic package 704. A first end of the pogo pin 760 is in physical contact with ground potential on the electrical circuit within the electronic package 704. A second end of the pogo pin 760 extends out of the aperture 756 and in the direction of the commonly grounded surface 732. The commonly grounded surface 732 may optionally have an indention 788 for receiving the second end of the pogo pin 760. The indention may improve the die ground connection between the electronic package 704 and the commonly grounded surface 732. A plane representing the commonly grounded surface 732 is shown above the electronic package 704 and arrows 734 indicate that the commonly grounded surface 732 will be moved in the direction of the electronic package 704.

In the top, after installation illustration, the PCB 720 with an electronics package 704 mounted thereto is shown installed on the plane representing the commonly grounded surface 732. After installation, a first face of the electronics package 704 is in close proximity, but not in contact with the commonly grounded surface 732. However, the pogo pin 760 is in compressive contact with the commonly grounded surface 732, thereby connecting ground potential on the electrical circuit to the commonly grounded surface 732 without utilizing the PCB 720 as an intermediary.

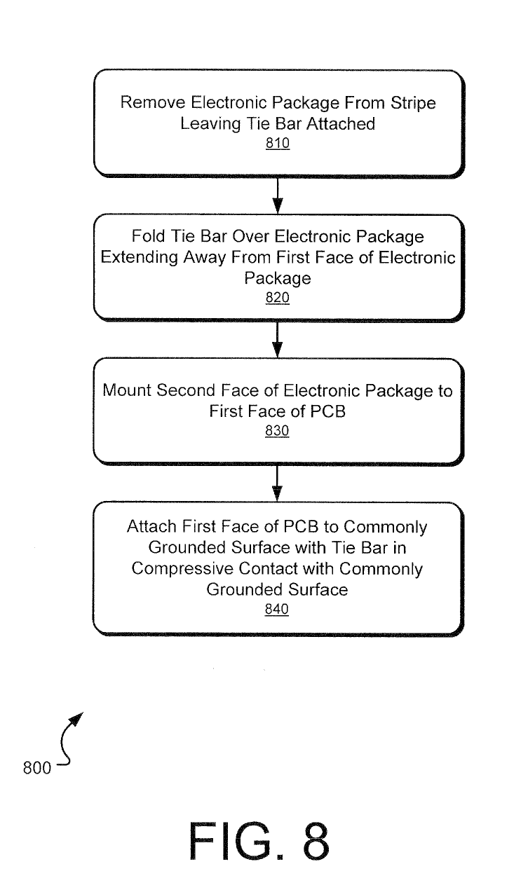

Referring now to FIG. 8, a flow chart illustrates an example process 800 for assembling an electrical system with an improved die ground lead. While the process in FIG. 8 is directed toward an implementation utilizing a tie bar as an improved die ground lead, other methods of attaching the improved die ground lead to an electronic package are contemplated.

The process begins with removing the electronic package from a stripe of electronic packages 810. Normally, the process of removing an electronic package from the stripe would entail cutting the tie bars at the edge of the electronic package. However, in at least one implementation of the described technology, one or more tie bars extending from one or more corners of the electronic package are left intact and attached to the electronic package. The tie bars may then be folded over a first face of the electronic package while also extending away from the first face of the electronic package 820.

Then the second face of the electronic package is attached to a PCB via signal and ground leads 830. Finally, the first face of the PCB is mounted to the commonly grounded surface with the first face of the electronic package in close proximity to but not contacting the commonly grounded surface. Since the tie bar extends away from the first face of the electronic package, when the PCB is mounted to the commonly grounded surface, the tie bar compressively contacts the commonly grounded surface thereby establishing the improved die ground connection 840.

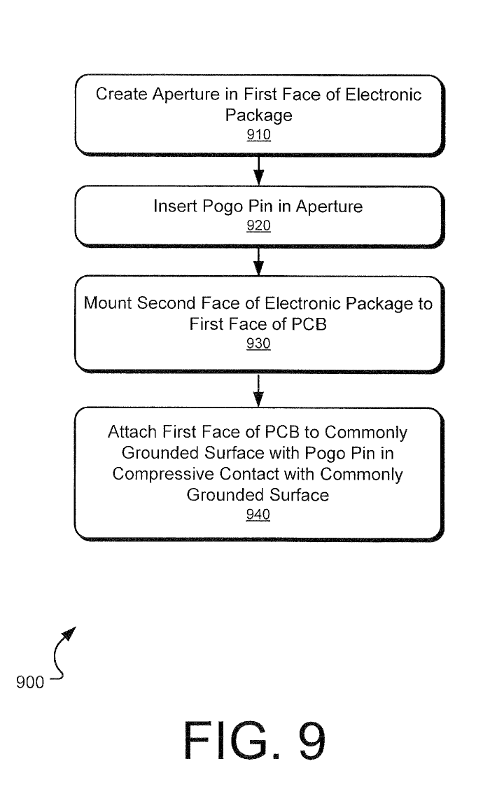

Referring now to FIG. 9, a flow chart illustrates another example process 900 for assembling an electrical system with an improved die ground lead. While the process in FIG. 9 is directed toward an implementation utilizing a pogo pin as an improved die ground lead, other methods of attaching the improved die ground lead to an electronic package are contemplated.

The process begins with creating an aperture in the over mold on a first face of an electronic package 910. The aperture may be formed at the time the over mold is installed on the electronic package or afterward. Further, drilling, melting, punching, or any means of creating an aperture may be used to create the aperture in the over mold. At the bottom of the aperture in the over mold is a connection to ground potential of the electrical circuit within the electronic package. This connection to ground potential may be to the die directly, to the lead frame, or to a wire or lead connected to the die and/or the lead frame.

Next a pogo pin or other compressive conductive device, e.g., a spring, is inserted into the aperture 920. Then the second face of the electronic package is attached to a PCB via signal and ground leads 930. Finally, the first face of the PCB is mounted to the commonly grounded surface with the first face of the electronic package in close proximity to but not contacting the commonly grounded surface. Since the pogo pin extends away from the first face of the electronic package, when the PCB is mounted to the commonly grounded surface, the pogo pin compressively contacts, rather than being bonded or soldered to, the commonly grounded surface thereby establishing the improved die ground connection 940.

The above specification and examples provide a complete description of the structures of example implementations of methods and apparatus that may be used for providing an improved die ground lead. Although various implementations of the methods and apparatus have been described above with a certain degree of particularity, or with reference to one or more individual implementations, those skilled in the art could make numerous alterations to the disclosed implementations without departing from the spirit or scope of the presently disclosed technology. It is intended that all matter contained in the above description and shown in the accompanying drawings shall be interpreted as illustrative only of particular implementations and not limiting. Changes in detail or structure may be made without departing from the basic elements of the presently disclosed technology as defined in the following claims.

What is claimed:

1. An electronic device in an electrical system comprising:
an electronic package including an electrical circuit and an internally grounded lead extending externally through the electronic package compressively electrically connecting the electrical circuit to a commonly grounded surface of the electrical system.

2. The electronic device of claim 1, wherein the lead comprises a tie bar positioned between the electronic package and the commonly grounded surface.

3. The electronic device of claim 1, wherein the lead comprises a pogo pin positioned between the electronic package and the commonly grounded surface.

4. The electronic device of claim 1, wherein the lead comprises a spring positioned between the electronic package and the commonly grounded surface.

5. The electronic device of claim 1, wherein the electrical system is a hard disk drive.

6. The electronic device of claim 1, wherein the electronic device includes a lead frame.

7. The electronic device of claim 1, wherein the electronic circuit has a first face and a second face wherein the second face is adapted to adjoin a printed circuit board and the first face is positioned between the printed circuit board and the commonly grounded surface.

8. An electronic device in an electrical system, the electrical system including a commonly grounded surface and a printed circuit board, the electronic device comprising:
an electronic package including an electrical circuit having a first face and a second face, wherein the second face is adapted to adjoin the printed circuit board and the first face is positioned between the printed circuit board and the commonly grounded surface; and
an internally grounded lead compressively electrically connecting the electrical circuit within the electronic package to the commonly grounded surface in the electrical system.

9. The electronic device of claim 8, wherein the means for compressively electrically connecting the electrical circuit within the electronic package to the commonly grounded surface in the electrical system comprises:
a lead internally grounded to the electronic package and extending away from the first face of the electronic package, wherein the lead forms a compressive electrical connection to the commonly grounded surface.

10. The electronic device of claim 9, wherein the lead comprises a tie bar positioned between the electronic package and the commonly grounded surface.

11. The electronic device of claim 8, wherein the electrical system is a hard disk drive.

12. The electronic device of claim 8, wherein the electronic device includes a lead frame.

13. The electronic device of claim 8, wherein the electronic device includes a Thin Quad Flat Pack.

14. A method, the method comprising:
compressively electrically connecting a ground lead of an electrical circuit within an electronic package to a commonly grounded surface, wherein the electronic package is mounted on a printed circuit board and the ground lead extends through the electronic package and away from the printed circuit board.

15. The method of claim 14, wherein the compressively electrically connecting operation comprises:
attaching the printed circuit board to the commonly grounded surface so that the electronic package is positioned between the printed circuit board and the commonly grounded surface and the ground lead is compressively electrically connected to the commonly grounded surface.

16. The method of claim 14, wherein the ground lead is at least one tie bar.

17. The method of claim 14, wherein the ground lead is at least one pogo pin.

18. The method of claim 14, wherein the ground lead is at least one spring.

19. The method of claim 14, further comprising:
removing the electronic package from a wafer containing a series of electronic packages leaving at least one tie bar extending through the electronic package; and
folding the free end of the at least one tie bar over the first face of the electronic package.

20. The method of claim 14, further comprising:
creating an aperture in a first face of the electronic package terminating at a ground connection within the electronic package; and
inserting at least one pogo pin in the aperture.
